(19) United States
(12) Patent Application Publication
(10) Pub. No.: US 2017/0352216 A1
(43) Pub. Date: Dec. 7, 2017

(54) ACCESS CONTROL SYSTEM SENSOR

(71) Applicant: Sargent Manufacturing Company, New Haven, CT (US)

(72) Inventor: Edward Donovan, Hartford, CT (US)

(73) Assignee: Sargent Manufacturing Company, New Haven, CT (US)

(21) Appl. No.: 15/596,559

(22) Filed: May 16, 2017

Related U.S. Application Data
(60) Provisional application No. 62/345,176, filed on Jun. 3, 2016.

(51) Int. Cl. G07C 9/00; E05B 17/22; H03K 17/955

(52) U.S. Cl. CPC G07C 9/00944; H03K 17/955; E05B 17/22; G07C 9/00111; G07C 9/00119

(57) ABSTRACT

Systems and methods for controlling access through a door are provided. Certain of the systems and methods described herein include a detection sensor that detects the proximity or contact by a user to a door handle or other portion of a door. According to one aspect, upon detection of such proximity or contact, a reader is controlled to change from a low power mode to an operational mode to read a credential. According to another aspect, upon detection of such proximity or contact, an access notification system generates a perceptible signal inside the access-controlled location that a user is at the door.

### RELATED APPLICATIONS

This Application claims the benefit under 35 U.S.C. §119(e) to U.S. Provisional Application Ser. No. 62/345,176, entitled “DOOR HANDLE ENGAGED SENSOR” filed on Jun. 3, 2016, which is herein incorporated by reference in its entirety.

### FIELD OF THE DISCLOSURE

This disclosure relates to electronic access control systems.

### BACKGROUND

Radio frequency identification (“RFID”) tags are widely used in identification badges or other types of access cards to gain access to a secured location, e.g., a building, a fenced facility, etc., by opening a lock on an access control point, e.g., a door, gate, etc. Such badges or cards (often referred to as “credentials”) are typically held within a certain distance of an RFID reader mounted to the access control point to authenticate the holder of the credential. Often, such RFID readers are powered by a local, stored source of power, such as a battery.

To determine if a credential is being presented to be read, RFID readers typically send out interrogation signals (often referred to as “pinging”) to detect the presence of an item to be read.

### SUMMARY

According to one aspect, an access control system for controlling access through a door is provided. The access control system may include a door, a detection sensor configured to generate an output signal indicating a user contacting or in proximity to the door, and an electronic lock. The access control system may include a controller connected to the detection sensor by a signal path and configured to receive the output signal from the detection sensor. The access control system may include a reader connected to the controller by a signal path and configured to read a credential presented to the reader to operate the electronic lock, wherein, upon receipt of the output signal from the detection sensor, the controller is configured to generate a signal to be communicated to the reader and cause the reader to change states from a low power mode in which the reader cannot read a credential to an operational mode in which the reader is able to read a credential.

According to another aspect, an access control system for controlling access through a door is provided. The access control system may include a door and a detection sensor configured to generate an output signal indicating a user contacting or in proximity to the door. The access control system may include an access notification system connected directly or indirectly to the detection sensor and configured to generate a perceptible signal that a user is at the door when the detection sensor generates the output signal.

According to yet another aspect, a method of controlling access through a door is provided. The method may include generating an output signal when a detection sensor senses a user contacting or in proximity to a door. The method may include receiving the output signal with a controller, and in response, controlling a reader to change from a low power mode in which the reader cannot read a credential to an operational mode in which the reader is able to read a credential. The method may include reading a credential with the reader and unlocking the door to permit access through the door.

### BRIEF DESCRIPTION OF THE DRAWINGS

The accompanying drawings, which are incorporated herein and form part of the specification, illustrate various embodiments of the subject matter of this disclosure. In the drawings, like reference numbers indicate identical or functionally similar elements.

FIG. 1 is a block diagram of an ingress access control sensor system;

FIG. 2 is a block diagram of an egress access control sensor system including a privacy feature;

FIG. 3 is a block diagram of an ingress access control sensor system including an access notification system;

FIG. 4 is a block diagram of an egress access control sensor system including an access notification system;

FIG. 5 depicts a time plot of an output signal emitted by an access control detection sensor;

FIG. 6 is a schematic view of an exemplary installation of a resistive sensor system;

FIG. 7 is a schematic view of an exemplary installation of a capacitive sensor system;

FIG. 8 depicts a resistive conditioning circuit;

FIG. 9 depicts a capacitive conditioning circuit; and

FIG. 10 is a block diagram of an illustrative computing device that may be used to implement a method of controlling an electronic access control system.

### DETAILED DESCRIPTION

RFID readers typically send out interrogation signals (“pinging”) to detect the presence of an item to be read. The RFID reader may operate in a reduced power-consumption state while it is pinging, and then power up to read a credential after the pinging indicates a credential may be present.

The inventors have recognized that, often times, pinging merely identifies the presence of something, and not necessarily a credential to be read. This may result in a false read whereby the RFID reader powers up and attempts to read a credential when no credential is actually present to be read.

The inventors have appreciated that one challenge with RFID readers is power consumption due to false reads as well as the constant pinging required to determine if the reader should be powered up to attempt to read a credential. The inventors have thus appreciated the need for an access control system that reduces power consumption.

According to one aspect, a detection sensor may be used to detect whether a person has interacted with an access control point, e.g., a door handle. With such a detection sensor, the reader electronics can be kept in low power, non-interrogating (“sleep”) mode until a person is ready to present a credential to the reader, at which time the reader may be powered-up (awakened) to send out an interrogation signal to read the credential. After a period of time, a successful read (verifying the credential), or a specified number of unsuccessful reads (unable to verify the credential), or after a user releases a door handle or otherwise disengages the detection sensor, the reader can go back into the low-power mode. In some embodiments, the detection sensor may comprise a capacitive proximity sensor and/or a resistive pressure sensor. Such an arrangement may permit an access control system to stay in low power mode until a user is ready to attempt to gain access to the door, which may decrease energy usage by the access control system. For battery-powered access controls systems, such an arrangement may help to prolong battery life.

In some embodiments, the detection sensor may output a signal that would behave similar to a Form A momentary switch. The output of the detection sensor may generate a pulse with a rising edge and falling edge. The pulse duration may be as long as the operator applies pressure or is in the proximity of the senor, depending on the technology used, e.g., capacitive or resistive. In some embodiments, the detection sensor may have a two wire output (e.g., a voltage output signal wire and a ground wire), and the output signal may be analog. A circuit may be required to condition the signal (e.g., to linearize the signal and prepare the signal to be digitized for processing by the microcontroller) before being input to a microcontroller unit (“MCU”) or other systems.

The MCU may execute specific firmware and may place the RFID reader in a low power (“sleep”) mode until an interrupt, triggered by an output signal from the detection sensor, wakes up the sleeping RFID reader. In some embodiments, an interrupt of the MCU may be a pin change, e.g., an input signal's falling or rising edge, that causes the MCU to take an action or change states. The systems described herein may save energy by preventing false card reads and pinging by the RFID reader when no credentials are in range of the reader (i.e., sending out radio interrogations signals even if no credential is in the vicinity to be read).

Other features and characteristics of the subject matter of this disclosure, as well as the methods of operation, functions of related elements of structure and the combination of parts, and economies of manufacture, will become more apparent upon consideration of the following description and the appended claims with reference to the accompanying drawings, all of which form a part of this specification, wherein like reference numerals designate corresponding parts in the various figures.

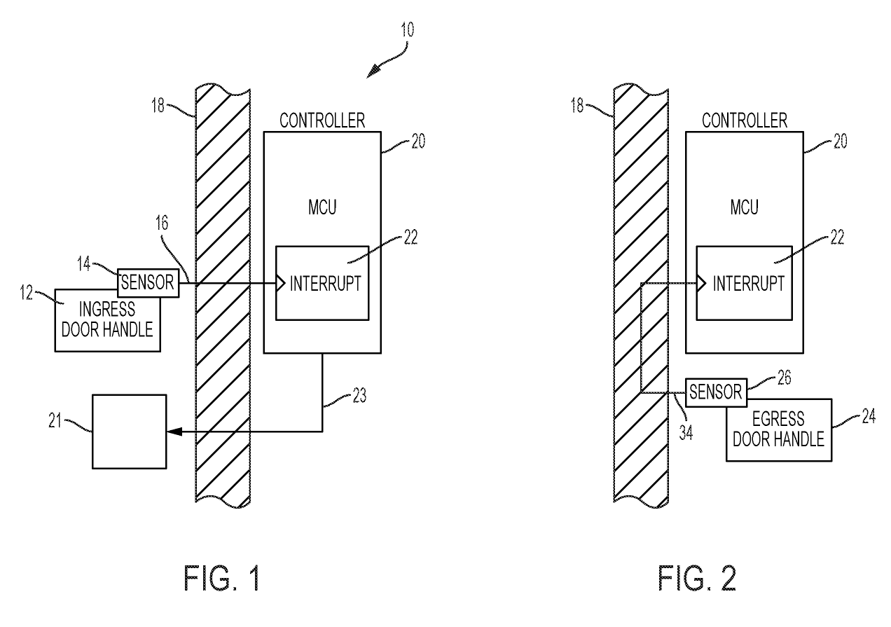

A block diagram of an access control sensor system 10 according to some embodiments is shown in FIG. 1. A door handle, represented by block 12, may be attached or otherwise coupled to a door 18. A detection sensor, represented by block 14, may be integrated into the body of the door handle or other apparatus by which a user operates the door handle, or is affixed to the surface of the door handle or other apparatus by which a user operates the door handle. An output signal from the detection sensor 14 may be communicated via a signal path 16 to an interrupt pin of an MCU, represented by block 22, of a controller, represented by block 20. A signal path may comprise any means by which an electronic signal, e.g., a voltage, is transmitted from one component, such as a sensor or other component that generates the signal, to another component, such as a component that processes the signal and/or stores the signal. In various embodiments, the signal path may comprise one or more conductor wires (and one or more of the wires may include an insulating covering) or it may comprise a wireless path with signal transmitting and signal receiving components on opposite ends of the path. An RFID reader, represented by block 21, may be mounted on or near the door and may be communicatively coupled to the controller 22 via a signal path 23 (e.g., comprising an SPI bus on wires extending through the door 18 to the reader 21). In one embodiment, upon receiving the signal from the detection sensor 14 indicating that a user is attempting ingress through the door 18 (e.g., the detection sensor is operatively engaged by the user), the MCU interrupt 22 may cause a “wakeup” signal to be communicated from the controller 20 to the RFID reader 21 to wake the RFID reader and cause the reader to begin pinging in search of a credential or begin an actual credential-reading sequence. The interaction between the detection sensor 14, the controller 20, the MCU (interrupt) 22, and the RFID reader 21 may be controlled by appropriate firmware.

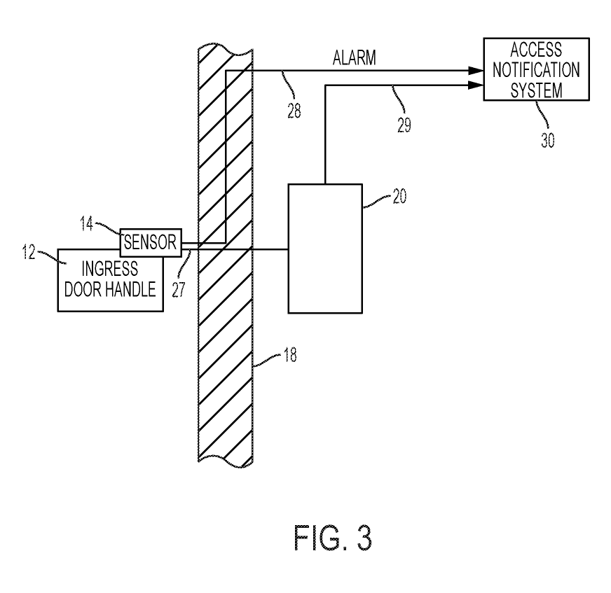

In various embodiments, as shown in FIG. 3, the system may include an access notification system, represented by block 30 in FIG. 3, that may receive a signal via signal path 28 and generate an alarm indicating that a person may be attempting ingress through a particular access point. The “alarm” signal may be communicated directly to the access notification system 30 as an output from the detection sensor 14 via signal path 28, as depicted in FIG. 3, or the signal may come from controller 20 via signal path 29 after an output signal from the detection sensor 14 indicating the presence of a user at the door is sent to the controller 20 via signal path 27. Thus, an output signal generated by the detection sensor 14 may raise an alarm (e.g., a perceptible auditory, visual, or tactile indicator) in an access control system 30 that indicating that a person may be attempting ingress through a particular access point.

In various embodiments, the access notification system 30 may include a doorbell system. Detection sensor 14 in the ingress door handle 12 can be engaged to generate an output signal via the access control system 30 to indicate that a user wishes to enter the door, triggering a doorbell or other indicator that is perceptible by others, e.g., person(s) inside the access controlled location.

The interaction between the detection sensor 14, the controller 20, and the access notification system 30 may be controlled by appropriate firmware.

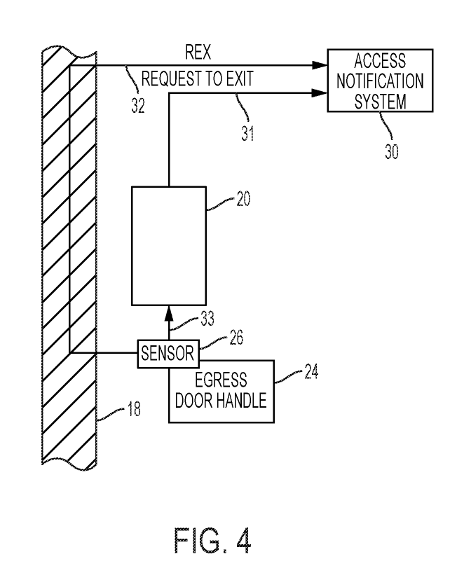

In various embodiments, as shown in FIG. 4, the access notification system 30 may receive a signal via communication path 32 and generate an alarm indicating that a person may be attempting egress through a particular access point. A detection sensor, represented by block 26 in FIG. 4, can be integrated with an egress handle, such as a lever or knob, represented by block 24 in FIG. 4, for opening the access point (e.g., door 18), replacing or supplementing the traditional REX (Request to Exit) signal in the lock body. In various embodiments, a REX signal may tell an access controller that the door 18 has been opened from the egress door handle 24 (inside lever). Traditionally, such REX signals have been generated using a mechanical limit switch or a reed switch integrated in the lock body in which case the REX signal is generated when the lock body is actuated in some fashion for ingress or egress. The REX signal may be used in conjunction with a door latch signal that indicates when the door latch has been retracted to allow the door to open. If a latch signal is received without a corresponding REX signal, this is an indication that the door may have been forced open.

Detection sensor 26 can be used to replace or supplement the REX switch within the lock body by indicating that an operator is in proximity or has engaged the egress door lever. In various embodiments, the detection sensor 26 may be provided as a retrofit whereby a REX signal can be provided in a door latch system that does not include the mechanical limit switch or a reed switch as described above.

The interaction between the detection sensor 26, the controller 20, and the access notification system 30 may be controlled by appropriate firmware.

The exit “alarm” signal may be communicated directly to the access notification system from the detection sensor 26 via signal path 32, as depicted in FIG. 4, or the detection sensor 26 may be connected to controller 20 via signal path 33 after an output signal from the detection sensor 26 indicating the presence of a user at the egress door handle 24 is sent to the controller, and the exit alarm signal is transmitted by the controller 20 to the access notification system 30 via a signal path 31. Thus, a signal generated by the detection sensor 26 may raise an alarm (e.g., a perceptible auditory, visual, or tactile indicator) in an access control system 30 indicating that a person may be attempting egress through a particular access point.

In various embodiments, as shown in FIG. 2, the system may include a privacy feature whereby an egress detection sensor 26 or other control device may be provided, e.g., on the egress handle 24, to allow a user to activate the privacy feature when the user does not want to permit entry to others. In some embodiments, detection sensor 26 is directly or indirectly connected via communication path 34 to the MCU interrupt 22, and the privacy feature may operate logically like a deadbolt that prevents entry into the access controlled location, for example, by programming the controller 20 to not open the lock when the privacy feature has been activated.

In some embodiments, an access control system for controlling access through a door may include an egress handle for operating the door to exit an access-controlled location through the door. The access control system may include a detection sensor mounted on or embedded into a portion of the egress handle and may be configured to generate an output signal when a user contacts or is in proximity to the egress handle. The access control system may include an electronic lock. The access control system may include a controller connected to the detection sensor by a signal path and may be configured to receive the output signal from the detection sensor. Upon receiving an output signal from the detection sensor, the controller may be configured to prevent the electronic lock from opening.

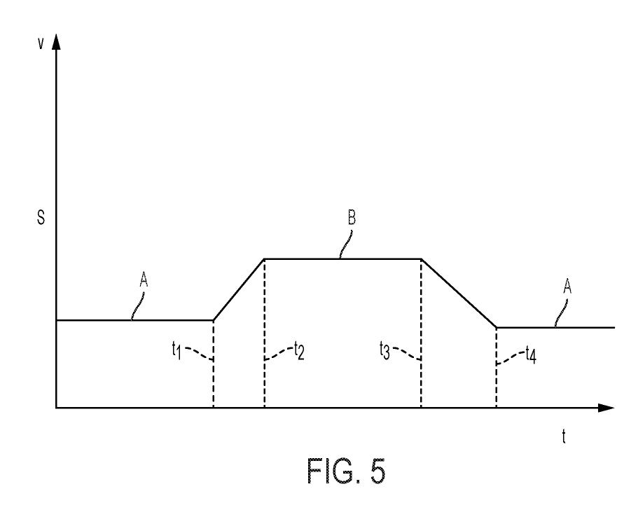

In some embodiments, the detection sensor is a capacitive proximity sensor on the handle, e.g. integrated into the body of the handle or affixed on the surface of the handle. Referring to FIG. 5, which is a time plot of a signal “S” emitted by a detection sensor, when the detection sensor is not activated—e.g., a user is not in proximity to the handle or is not touching the handle—the signal S emitted by the detection sensor is at a low steady-state level “A” and the MCU interrupt 22 is in low power sleep mode. When an operator moves their hand in the proximity of the detection sensor at time t₁, the detection sensor output signal increases in voltage toward level “B”, creating a rising edge beginning at time t₁. When the operator has contacted the handle 12—resulting in engagement of the detection sensor at time t₂—the output signal plateaus at level “B,” and the MCU interrupt 22 is switched to full power in active interrogation mode, also referred to as an operative mode. In the operative mode, the reader is able to read a credential. The output signal S stays at steady state level B—and the MCU interrupt 22 remains active—until the operator begins to let go of the handle 12 at time t₃. The action of releasing the handle 12 creates a falling edge in the output signal S beginning at time t₃, and the output signal returns to level A at time t₁ when the operator has released the handle 12 and moved away from the detection sensor. Beginning at time t₄, the MCU interrupt 22 returns to a low power mode, also called a sleep mode. In the low power mode, the reader is unable to read a credential.

In some embodiments, the detection sensor is a resistive force sensor on the handle, e.g. integrated into the body of the handle or affixed on the surface of the handle. In some embodiments, the resistive force sensor may be sensitive enough to detect contact of the handle by a user. The output of the force sensor can be linearized and conditioned to detect varying amounts of pressure, creating a threshold. Before an user contacts the handle 12, the output signal S is at the lower level A and the MCU interrupt 22 is in low power sleep mode. As a user begins to contact the handle 12 with the resistive sensor at time t₁ and applies pressure exceeding the threshold, the detection sensor output signal S increases in voltage from the steady state, low level A, creating a rising edge beginning at time t₁. Once the operator has contacted the handle 12 at time t₂, the output signal S reaches a plateau level B, and the MCU interrupt 22 is switched to full power, active interrogation mode. The output signal S stays at steady state level B—and the MCU interrupt 22 remains active—until the operator begins to let go of the handle 12 at time t₃. The action of releasing the lever creates a falling edge in the output signal S beginning at time t₃, and the output signal returns to level A at time t₄ when the operator has released the handle 12. Beginning at time t₄, the MCU interrupt 22 returns to a low power mode.

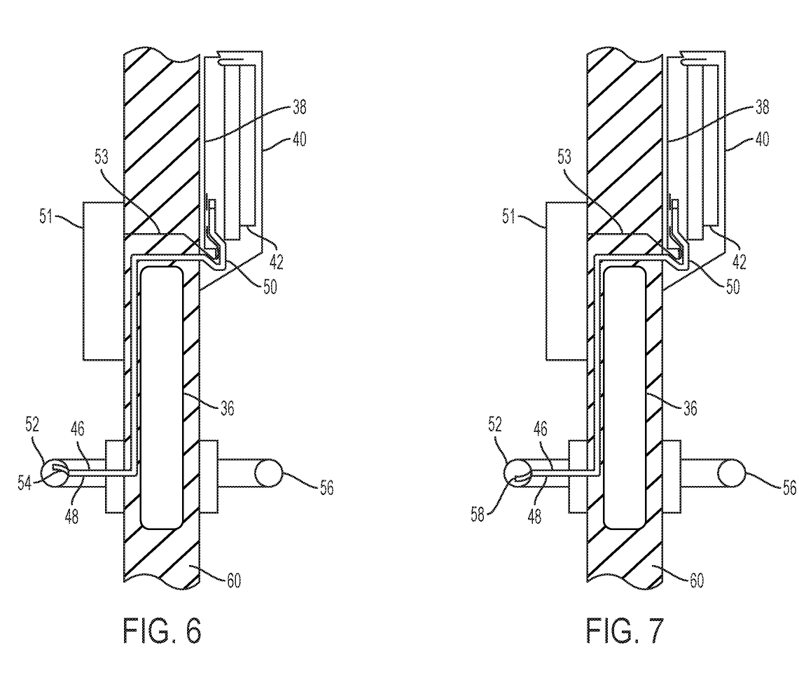

Exemplary installations of a sensor system 10 are shown in FIGS. 6 and 7. In FIG. 6, a door 60 has an ingress handle 52 and an egress handle 56. A lock body 36 may be mounted within the door 60. Lock body 36 may, for example, comprise a mortise lock with an electronic cylinder. Other types of lock bodies may be used, such as a bored lock and exit device. The exit device can be a surface vertical rod, concealed vertical rod, RIM, or mortise. A controller 42 may be mounted on a metal back plate 38 on the inside surface of the door 60 and may be covered by an inside escutcheon 40. A detection sensor 54 (e.g., a capacitive sensor) may be embedded within the ingress handle 52 and may be connected by a first wire 46 (e.g., a signal wire) and a second wire 48 (e.g., a ground wire) to the controller 42. A wiring harness 50 may be provided for connecting the controller 42 to the lock body 36. A reader 51 (e.g., an RFID reader) attached to an outer surface of the door 60 may be connected to the controller 42 by wire 53 (wire 53 may comprise one or more wires).

In FIG. 7, the installation is essentially identical to installation of FIG. 6, except that the detection sensor is a resistive sensor 58 that may be attached to the surface of the ingress handle 52.

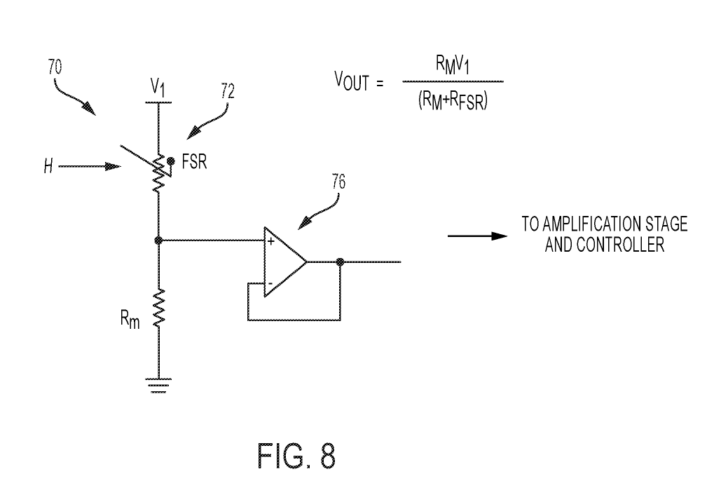

In some embodiments, an access control system may include a resistive conditioning circuit. FIG. 8 depicts one illustrative embodiment of a resistive conditioning circuit 70. The output voltage may increase with increasing force from the human “H” at the sensor resistor 72 (FSR—Force Sense Resister). The measuring resistor, R_{M}, may be chosen to maximize the desired force sensitivity range and to limit current. The voltage divider may be followed by an op-amp 76 to provide an impedance buffer. The output of the op-amp would go to an amplification and/or linearization stage, depending on the MCU, and then to the MCU. The output voltage is given by the formula:

Vₒᵤₜ=R_{M}V₁/(R_{M}+R_{FSR})

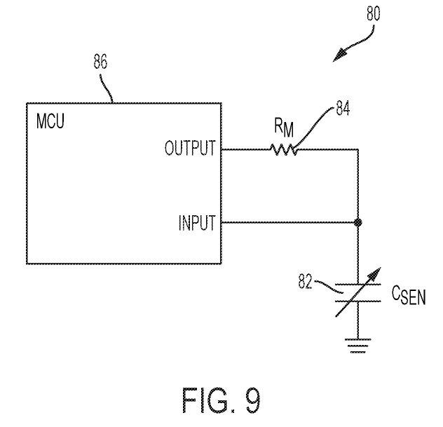

In some embodiments, an access control system may include a capacitive conditioning circuit. FIG. 9 depicts one illustrative embodiment of a capacitive conditioning circuit 80. The MCU 86 may produce a voltage at the output pin and measuring resistor, R_{M} 84. The circuit may have a single pole response to a step, producing an RC decay at the capacitive sensor C_{SEN} 82. The capacitance may be measured by determining the time it takes for the voltage to decay to a threshold.

It should be appreciated that various types of sensors may be used as a detection sensor to detect when a user is in contact with or in proximity to a portion of a door, such as a door handle. In some embodiments, the detection sensor may be a resistive sensor, a capacitive sensor, a photoelectric sensor, optical sensors, a piezoelectric sensor, an ultrasonic sensor, an infrared sensor, a surface acoustic wave sensor, or any other suitable sensor.

It should be appreciated that the detection sensor may be physically positioned at different locations in various embodiments. For example, in some embodiments, the detection sensor may be positioned on or in a door handle. In some embodiments, the detection sensor may be positioned on or in an escutcheon of a handle. In some embodiments, the detection sensor may be positioned on or in other portions of the door, such as a lock body, the body of the door itself (e.g., such as a door panel, door rail), the door frame, etc. In some embodiments, the detection sensor may be positioned on or in a component other than the door, such as the ceiling in an area above the door, or a portion of the floor in front of or near the door, or a portion of a wall next to or above the door.

In some embodiments, the detection sensor may be positioned in close proximity to the handle. In some embodiments, the detection sensor may be positioned at a distance of at least about 1 inch, at least about 6 inches, at least about 12 inches, at least about 24 inches, at least about 36 inches, at least about 48 inches, or at least about 60 inches away from the handle. In some embodiments, the detection sensor may be positioned at a distance of less than or equal to about 60 inches, less than or equal to about 48 inches, less than or equal to about 36 inches, less than or equal to about less than or equal to about 24 inches, less than or equal to about 12 inches, less than or equal to about 6 inches, or less than or equal to about 1 inch away from the handle. Combinations of the above-referenced ranges are also possible. For example, in some embodiments, the detection sensor may be positioned at a distance of about 1 inch to about 60 inches, about 6 inches to about 48 inches, about 6 inches to about 36 inches, about 6 inches to about 24 inches, or about 6 inches to about 12 inches away from the handle.

Examples of door handles include: levers, knobs, handle sets, door pulls (e.g., including flush door pulls, door pull plates and offset pull handles), door push plates, push bars (also known as a crash bar, panic exit device, panic bar), push paddles, pull paddles, or any other suitable door opening mechanism that is physically contacted by a user.

It should be appreciated that, in some embodiments, the door may not include a door handle. A user may open the door by pushing on the door, or the door may be an automatic door. In some embodiments, if the door does not have a handle, the detection sensor may be used to detect when a user is contacting the door or is in close proximity to the door.

According to one aspect, the detection sensor triggers a signal to indicate that a user wishes to open a door when the user is within a certain distance from the door. In some embodiments, the distance may be measured from a handle of the door, from a credential reader, from a center of the door (e.g., centered vertically and horizontally, on the surface of the door facing the user), or from any other portion of the door. In some embodiments, the detection sensor triggers the signal when a user is within a distance of at least about 1 inch, at least about 6 inches, at least about 12 inches, at least about 24 inches, at least about 36 inches, at least about 48 inches, or at least about 60 inches from the door. In some embodiments, the detection sensor triggers the signal when a user is within a distance of less than or equal to about 60 inches, less than or equal to about 48 inches, less than or equal to about 36 inches, less than or equal to about 24 inches, less than or equal to about 12 inches, less than or equal to about 6 inches, or less than or equal to about 1 inch from the door. Combinations of the above-referenced ranges are also possible. For example, in some embodiments, the detection sensor triggers the signal when a user is within a distance of about 1 inch to about 60 inches, within about 6 inches to about 48 inches, within about 12 inches to about 24 inches, or within about 12 inches to about 18 inches from the door.

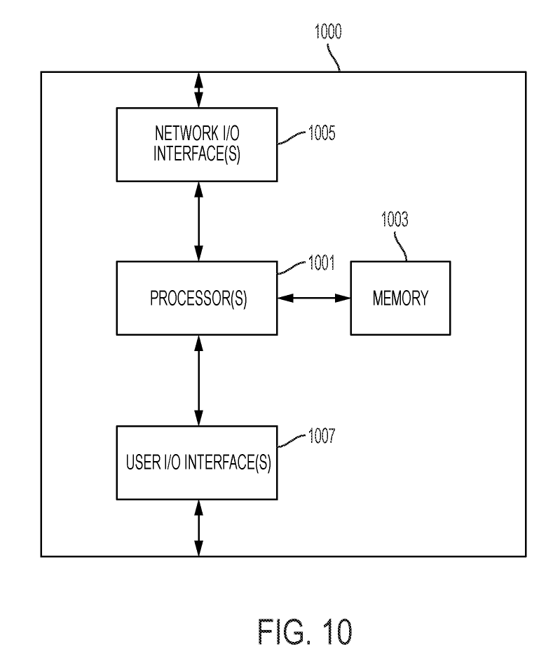

FIG. 10 is a block diagram of an illustrative computing device 1000 that may be used to implement any of the above-described techniques. Computing device 1000 may include one or more processors 1001 and one or more tangible, non-transitory computer-readable storage media (e.g., memory 1003). Memory 1003 may store, in a tangible non-transitory computer-recordable medium, computer program instructions that, when executed, implement any of the above-described functionality. Processor(s) 1001 may be coupled to memory 1003 and may execute such computer program instructions to cause the functionality to be realized and performed.

Computing device 1000 may also include a network input/output (I/O) interface 1005 via which the computing device may communicate with other computing devices (e.g., over a network), and may also include one or more user I/O interfaces 1007, via which the computing device may provide output to and receive input from a user. The user I/O interfaces may include devices such as a keyboard, a mouse, a microphone, a display device (e.g., a monitor or touch screen), speakers, a camera, and/or various other types of I/O devices.

The above-described embodiments can be implemented in any of numerous ways. For example, the embodiments may be implemented using hardware, software or a combination thereof. When implemented in software, the software code can be executed on any suitable processor (e.g., a microprocessor) or collection of processors, whether provided in a single computing device or distributed among multiple computing devices. It should be appreciated that any component or collection of components that perform the functions described above can be generically considered as one or more controllers that control the above-discussed functions. The one or more controllers can be implemented in numerous ways, such as with dedicated hardware, or with general purpose hardware (e.g., one or more processors) that is programmed using microcode or software to perform the functions recited above. In some embodiments, a combination of programmable hardware and dedicated hardware may also be used.

In this respect, it should be appreciated that one implementation of the embodiments described herein comprises at least one computer-readable storage medium (e.g., RAM, ROM, EEPROM, flash memory or other memory technology, CD-ROM, digital versatile disks (DVD) or other optical disk storage, magnetic cassettes, magnetic tape, magnetic disk storage or other magnetic storage devices, or other tangible, non-transitory computer-readable storage medium) encoded with a computer program (i.e., a plurality of executable instructions) that, when executed on one or more processors, performs the above-discussed functions of one or more embodiments. The computer-readable medium may be transportable such that the program stored thereon can be loaded onto any computing device to implement aspects of the techniques discussed herein. In addition, it should be appreciated that the reference to a computer program which, when executed, performs any of the above-discussed functions, is not limited to an application program running on a host computer. Rather, the terms computer program and software are used herein in a generic sense to reference any type of computer code (e.g., application software, firmware, microcode, or any other form of computer instruction) that can be employed to program one or more processors to implement aspects of the techniques discussed herein.

While the subject matter of this disclosure has been described and shown in considerable detail with reference to certain illustrative embodiments, including various combinations and sub-combinations of features, those skilled in the art will readily appreciate other embodiments and variations and modifications thereof as encompassed within the scope of the present disclosure. Moreover, the descriptions of such embodiments, combinations, and subcombinations is not intended to convey that the claimed subject matter requires features or combinations of features other than those expressly recited in the claims. Accordingly, the scope of this disclosure is intended to include all modifications and variations encompassed within the spirit and scope of the following appended claims.

While aspects of the subject matter of the present disclosure may be embodied in a variety of forms, the following description and accompanying drawings are merely intended to disclose some of these forms as specific examples of the subject matter. Accordingly, the subject matter of this disclosure is not intended to be limited to the forms or embodiments so described and illustrated.

Unless defined otherwise, all terms of art, notations and other technical terms or terminology used herein have the same meaning as is commonly understood by one of ordinary skill in the art to which this disclosure belongs. All patents, applications, published applications and other publications referred to herein are incorporated by reference in their entirety. If a definition set forth in this section is contrary to or otherwise inconsistent with a definition set forth in the patents, applications, published applications, and other publications that are herein incorporated by reference, the definition set forth in this section prevails over the definition that is incorporated herein by reference.

Unless otherwise indicated or the context suggests otherwise, as used herein, “a” or “an” means “at least one” or “one or more.”

This description may use relative spatial and/or orientation terms in describing the position and/or orientation of a component, apparatus, location, feature, or a portion thereof. Unless specifically stated, or otherwise dictated by the context of the description, such terms, including, without limitation, top, bottom, above, below, under, on top of, upper, lower, left of, right of, in front of, behind, next to, adjacent, between, horizontal, vertical, diagonal, longitudinal, transverse, radial, axial, etc., are used for convenience in referring to such component, apparatus, location, feature, or a portion thereof in the drawings and are not intended to be limiting.

Furthermore, unless otherwise stated, any specific dimensions mentioned in this description are merely representative of an exemplary implementation of a device embodying aspects of the disclosure and are not intended to be limiting.

The use of the term “about” applies to all numeric values specified herein, whether or not explicitly indicated. This term generally refers to a range of numbers that one of ordinary skill in the art would consider as a reasonable amount of deviation to the recited numeric values (i.e., having the equivalent function or result) in the context of the present disclosure. For example, and not intended to be limiting, this term can be construed as including a deviation of ±10 percent of the given numeric value provided such a deviation does not alter the end function or result of the value. Therefore, under some circumstances as would be appreciated by one of ordinary skill in the art a value of about 1% can be construed to be a range from 0.9% to 1.1%.

As used herein, the term “set” refers to a collection of one or more objects. Thus, for example, a set of objects can include a single object or multiple objects. Objects of a set also can be referred to as members of the set. Objects of a set can be the same or different. In some instances, objects of a set can share one or more common properties.

As used herein, the term “adjacent” refers to being near or adjoining. Adjacent objects can be spaced apart from one another or can be in actual or direct contact with one another. In some instances, adjacent objects can be coupled to one another or can be formed integrally with one another.

As used herein, the terms “substantially” and “substantial” refer to a considerable degree or extent. When used in conjunction with, for example, an event, circumstance, characteristic, or property, the terms can refer to instances in which the event, circumstance, characteristic, or property occurs precisely as well as instances in which the event, circumstance, characteristic, or property occurs to a close approximation, such as accounting for typical tolerance levels or variability of the embodiments described herein.

As used herein, the terms “optional” and “optionally” mean that the subsequently described, component, structure, element, event, circumstance, characteristic, property, etc. may or may not be included or occur and that the description includes instances where the component, structure, element, event, circumstance, characteristic, property, etc. is included or occurs and instances in which it is not or does not.

What is claimed is:

1. An access control system for controlling access through a door, comprising:
a door;
a detection sensor configured to generate an output signal indicating a user contacting or in proximity to the door;
an electronic lock;
a controller connected to the detection sensor by a signal path and configured to receive the output signal from the detection sensor; and
a reader connected to the controller by a signal path and configured to read a credential presented to the reader to operate the electronic lock, wherein, upon receipt of the output signal from the detection sensor, the controller is configured to generate a signal to be communicated to the reader and cause the reader to change states from a low power mode in which the reader cannot read a credential to an operational mode in which the reader is able to read a credential.

2. The access control system of claim 1, wherein the door further comprises a handle for operating a door to gain access through the door, wherein the detection sensor is configured to generate the output signal indicating a user contacting or in proximity to the handle.

3. The access control system of claim 2, wherein the detection sensor is mounted on or embedded into a portion of the handle.

4. The access control system of claim 1, wherein the detection sensor is a force resistive sensor.

5. The access control system of claim 1, wherein the detection sensor is a capacitive proximity sensor.

6. The access control system of claim 1, wherein the reader is an RFID reader and the credential is an RFID tag.

7. The access control system of claim 2, wherein the handle is an ingress handle.

8. The access control system of claim 2, wherein the handle is an egress handle.

9. An access control system for controlling access through a door, comprising:
a door;
a detection sensor configured to generate an output signal indicating a user contacting or in proximity to the door; and
an access notification system connected directly or indirectly to the detection sensor and configured to generate a perceptible signal that a user is at the door when the detection sensor generates the output signal.

10. The access control system of claim 9, wherein the door further comprises a handle for operating a door to gain access to an access-controlled location through the door.

11. The access control system of claim 10, wherein the detection sensor is mounted on or embedded into a portion of the handle.

12. The access control system of claim 9, wherein the detection sensor is a force resistive sensor.

13. The access control system of claim 9, wherein the detection sensor is a capacitive proximity sensor.

14. The access control system of claim 10, wherein the handle comprises an ingress handle.

15. The access control system of claim 10, wherein the handle comprises an egress handle.

16. The access control system of claim 10, wherein the door leads to an access-controlled location and the perceptible signal is generated inside the access-controlled location.

17. A method of controlling access through a door, comprising:
generating an output signal when a detection sensor senses a user contacting or in proximity to a door;
receiving the output signal with a controller, and in response, controlling a reader to change from a low power mode in which the reader cannot read a credential to an operational mode in which the reader is able to read a credential;
reading a credential with the reader; and
unlocking the door to permit access through the door.

18. The method of claim 17, wherein the door further comprises a handle, the handle being used to operate the door to gain access through the door.

19. The method of claim 18, wherein the detection sensor is mounted on or embedded into a portion of the handle.

20. The method of claim 17, wherein the detection sensor is a force resistive sensor.

21. The method of claim 17, wherein the detection sensor is a capacitive proximity sensor.

22. The method of claim 18, wherein the detection sensor is embedded in the handle.

23. The method of claim 17, wherein the reader is an RFID reader and the credential is an RFID tag.

24. The method of claim 18, wherein the handle is an ingress handle.

25. The method of claim 18, wherein the handle is an egress handle.
